(19) United States
(12) Patent Application Publication
(10) Pub. No.: US 2020/0251644 A1
(43) Pub. Date: Aug. 6, 2020

(54) THERMOELECTRIC GENERATOR COMPRISING LIQUID METAL HEAT EXCHANGE UNIT

(71) Applicant: KOREA INSTITUTE OF INDUSTRIAL TECHNOLOGY, Chungcheongnam-do (KR)

(72) Inventors: Uen Do LEE, Daejeon (KR); Won YANG, Gyeonggi-do (KR); Byung Ryeul BANG, Seoul (KR); Ji Hong MOON, Chungcheongnam-do (KR)

(21) Appl. No.: 16/832,326

(22) Filed: Mar. 27, 2020

Related U.S. Application Data
(62) Division of application No. 15/322,501, filed on Dec. 28, 2016.

(30) Foreign Application Priority Data
Jun. 30, 2014 (KR) 10-2014-0080837

(51) Int. Cl. H01L 35/30

(52) U.S. Cl. CPC H01L 35/30

(57) ABSTRACT

The present invention relates to a thermoelectric generator comprising a liquid metal heat exchanger, the thermoelectric generator comprising: a thermoelectric element; a power generation unit electrically connected to the thermoelectric element; a liquid metal heat exchange unit, which is connected to the high-temperature side of the thermoelectric element and has a liquid metal flowing therein; and a heat source unit connected to the liquid metal heat exchange unit so as to exchange heat therewith.

The present application claims priority to U.S. application Ser. No. 15/322,501, filed Dec. 28, 2016, which is a 371 National Stage Filing of PCT Application No. PCT/KR2015/006016, filed Jun. 15, 2015, and Korean Patent Application No. 10-2014-0080837, filed on Jun. 30, 2014 in the Republic of Korea, the disclosures of which are incorporated herein by reference.

### TECHNICAL FIELD

The present disclosure relates to a thermoelectric generator comprising a liquid metal heat exchanger, and to a thermoelectric generator using thermoelectric element, which uses liquid metal as a heat exchanging medium to exchange heat with the thermoelectric element. More specifically, the present disclosure relates to a thermoelectric generator which generates electricity by supplying heat generated from a heat source unit at a temperature optimized for the power generation of the thermoelectric element by using liquid metal flowing inside a liquid metal heat exchange unit as the heat exchange medium, or by supplying the heat generated from high-temperature part of the thermoelectric element to the liquid metal heat exchange unit.

### BACKGROUND ART

The thermoelectric element is the element that utilizes thermoelectric phenomenon in which heat energy is converted into electrical energy as the difference of temperatures on each ends of the element are converted into electricity, or in which electricity is flowing through the element to generate to difference of temperatures at each end of the element so that electric energy is converted into heat energy. Such thermoelectric element is adapted for use in cooling apparatus, heating apparatus, or power generating apparatus, and the present disclosure relates to a thermoelectric generator using the thermoelectric element.

In order to utilize sensible heat or waste heat of a boiler or the like, efforts are necessary in order to obtain a sufficient amount of energy. In this respect, mainly two efforts are being made to make technical developments for the methods to increase efficiency of thermoelectric element.

The first method is to effectively deliver a greater amount of heat energy to a high-temperature side of a thermoelectric element, and the second method is to effectively cool the heat energy transferred from the high-temperature side to the low-temperature side. That is, in order to increase power generation productivity and efficiency using the thermoelectric element, the low-temperature side is required to effectively cool the heat energy transferred from the high-temperature side.

Concerning this, the thermoelectric element is a system that generates electricity by the Seebeck effect as the heat generated from mid- to low-temperature region corresponding to several tens of degrees to several hundreds of degrees is transferred from the high-temperature side to the low-temperature side. Therefore, the ranges of the high-temperature side and the low-temperature side for the optimum operations is considerably constrained. Generally, setting temperature condition for the low-temperature side is possible by using heat exchange with atmosphere or water cooling, but in the high-temperature side, setting temperature condition is quite difficult.

Further, for a thermoelectric generator using waste heat as a heat source, it is necessary that the high-temperature side of the thermoelectric element is positioned directly in the waste heat source, while releasing heat to opposite direction. This causes numerous constraints for condition setting spatially as well as thermally.

Related prior art documents are discussed below.

KR Patent Publication No. 10-2012-0038335 discloses a prior art related to a thermoelectric generator that uses high-temperature heat from the exhaust gas released from a vehicle through a pipe, which adopts a method of using endothermic fins to absorb high-temperature heat to effectively deliver the waste heat inside the release pipe to outer walls, thus providing an effect of delivering a relatively larger amount of heat.

KR Patent Publication No. 10-2013-0066059 disclose a prior art relating to a thermoelectric generator for use in vehicle, which converts the heat energy of the exhaust gas from an engine into electrical energy by using thermoelectric phenomenon, and in which thermoelectric element is installed in contact with inner walls of a silencer such that the heat of the exhaust gas is effectively delivered to the thermoelectric element, thus enhancing efficiency of thermoelectric generation at the thermoelectric element.

Meanwhile, the related art technologies still do not take into consideration the temperature range suitable for driving a thermoelectric element. That is, the related art technologies do not consider means to provide the high-temperature side of the thermoelectric element with optimum temperature range delivered to the high-temperature side of the thermoelectric element, while such is necessary for enhancement of the thermoelectric generation efficiency.

Further, the related art technologies also do not consider spatial constraints of the thermoelectric generator using a thermoelectric element, which can be caused when the high-temperature side of the thermoelectric element is positioned directly at the heat source unit to be supplied with heat from the heat source unit to generate electricity.
(Patent Document 1) KR10-2012-0038335 A
(Patent Document 2) KR10-2013-0066059 A

### DISCLOSURE

### Technical Problem

According to an embodiment, a technical objective is to provide a thermoelectric power generator, which uses a thermoelectric element to absorb heat from a heat source unit reaching hundred degrees due to burning at thousand degrees or higher, with a suitable heat exchange medium, and which can adjust to a suitable temperature for driving of the thermoelectric element.

Another technical objective is to provide a thermoelectric generator that uses a thermoelectric element, which is capable of generating electricity without being limited by positions of a variety of heat source units that supply heat nor by spatial constraints.

Further, another technical objective is to provide a thermoelectric generator that uses a thermoelectric element, which enhances generation efficiency by ensuring that a sufficient amount of heat is transferred to high-temperature side of the thermoelectric element.

### Technical Solution

In order to solve the problems mentioned above, the thermoelectric generator according to the present disclosure includes a thermoelectric element 100, a power generation unit 200 electrically connected to the thermoelectric element 100, a liquid metal heat exchange unit 300, which is connected to a high-temperature side 120 of the thermoelectric element 100 so as to exchange heat therewith, and in which a liquid metal flows, and a heat source unit 400 connected to the liquid metal heat exchange unit 300 so as to exchange heat therewith.

Preferably, the liquid metal heat exchange unit 300 includes a first liquid metal heat exchanger 340 connected to the heat source unit 400, a second liquid metal heat exchanger 360 connected to the high-temperature side 120 of the thermoelectric element so as to exchange heat therewith, and a liquid metal storage unit 320 fluidly communicated with the first liquid metal heat exchanger 340 and the second liquid metal heat exchanger 360.

Preferably, the liquid metal circulates between the first liquid metal heat exchanger 340 and the liquid metal storage unit 320, and between the second liquid metal heat exchanger 360 and the liquid metal storage unit 320.

Preferably, the electricity produced at the generation unit 200 is supplied to the heat source unit 400 or to the liquid metal storage unit 320 so that heat necessary for initial driving is supplied.

Preferably, the liquid metal is composed of one or more of tin, bismuth, lead, and gallium.

Preferably, the thermoelectric generator further includes a water supply unit 500 connected to the low-temperature side 140 of the thermoelectric element 100, and a first hot water heat exchanger connected to the low-temperature side 140 of the thermoelectric element, and the first hot water heat exchanger 520 is connected to the heat source unit 400 so as to exchange heat therewith, and water supplied from the water supply unit 500 is passed the low-temperature side 140 of the thermoelectric element and then supplied to the first hot water heat exchanger 520.

Preferably, the thermoelectric generator further includes a second hot water heat exchanger 540 connected to the first hot water heat exchanger 520, and the second hot water heat exchanger 540 is connected to the liquid metal heat exchanger 300 so as to exchange heat therewith, and water past the first hot water heat exchanger 500 is supplied to the second hot water heat exchanger 540.

Preferably, the heat source unit 400 is a boiler, and the water supply unit 500 is connected to one or more of the first hot water heat exchanger 520 and the second hot water heat exchanger 540, and water is supplied from the water supply unit 500 to the first hot water heat exchanger 520 or water is supplied from the water supply unit 500 to the second hot water heat exchanger 540.

Preferably, the thermoelectric generator further includes a cooling unit 600 connected to the heat source unit 400, and the cooling unit 600 is connected to the low-temperature side 140 of the thermoelectric element 100, and a coolant of the cooling unit 600 is supplied to the low-temperature side 140 of the thermoelectric element.

Preferably, the heat source unit 400 includes one or more of automobile engine and automobile exhaust system, and the liquid metal cools the heat source unit 400 at a higher temperature condition than the cooling unit 600 while flowing in the liquid metal heat exchange unit 300, for the purpose of thermoelectric generation. The cooling unit 600 can be used when it is necessary to cool the heat source unit 400 at a temperature lower than a temperature cooled with the liquid metal.

Preferably, the coolant circulates between the low-temperature side 140 of the thermoelectric element and the cooling unit 600.

Preferably, the liquid metal storage unit 320 is at a lower end of the liquid metal heat exchangers 340, 360 so that when the liquid metal heat exchange unit 300 is not in operation, the liquid metal is entirely gravitated into the liquid metal storage unit 320 and stored therein, and once the liquid metal heat exchange unit 300 starts operating, the liquid metal is pumped with a pump (not illustrated) to be circulated in the liquid metal heat exchange unit 300.

Preferably, the liquid metal storage unit 320 is configured to keep the liquid metal at a temperature above predetermined degrees using exhaust gas from the heat source unit 400 by being in the vicinity to the heat source unit 400, and controls an amount of circulation by the pump (not illustrated), and a temperature of a liquid metal storage unit 320 with the second hot water heat exchanger 540 that passes the liquid metal heat exchanger 300.

### Advantageous Effects

According to the present disclosure, the thermoelectric generator with the means to solve the problems can efficiently absorb the heat generated from a heat source, and adjust the absorbed heat to a temperature range suitable for driving the thermoelectric element so that efficiency of the thermoelectric generator using the thermoelectric element is increased.

Further, the liquid metal has such characteristics that it is in liquid state at an optimum temperature range for delivery to a driving unit of the thermoelectric element, and has high heat capacity and low viscosity, thus allowing increased heat exchange efficiency and increased efficiency of the thermoelectric generator.

Further, since the heat generated from the heat source is delivered to the high-temperature side of the thermoelectric element through the liquid metal heat exchange unit, compared to related art where the high-temperature side of the thermoelectric element is positioned directly at the heat source, the present disclosure does not suffer spatial constraint for installation of the thermoelectric generator.

Further, when the thermoelectric generator according to the present disclosure is applied for use in an automobile engine, etc., the coolant to cool the engine can be used as a substitute for the liquid metal, thus satisfying both cooling and power generation needs at the same time. Further, since high-temperature waste heat generated from the engine can be recovered and utilized for power generation, energy utilization efficiency can be further increased.

Further, when the thermoelectric generator according to the present disclosure is applied for use in a boiler, etc., the thermoelectric generator can generate both electricity and hot water, and can achieve a form that greatly increases efficiency of utilizing energy by utilizing the heat remaining after power generation for the purpose of hot water generation.

### DESCRIPTION OF DRAWINGS

FIG. 1 schematically illustrates a thermoelectric generator according to a first exemplary embodiment of the present disclosure.

FIG. 2 schematically illustrates a thermoelectric generator according to a second exemplary embodiment of the present disclosure.

FIG. 3 schematically illustrates a thermoelectric generator according to a third exemplary embodiment of the present disclosure.

### BEST MODE

Hereinbelow, the present disclosure will be described in detail with reference to accompanying drawings. In the description, the lines or elements may be in illustrated in exaggerated thicknesses or sizes for clarity and convenience of explanation.

Further, the terms used herein are defined in consideration of the functions in the present disclosure, and these are subject to change depending on intention or practices of the users or operators. Accordingly, the definitions of these terms should be described based on the overall description of the present disclosure.

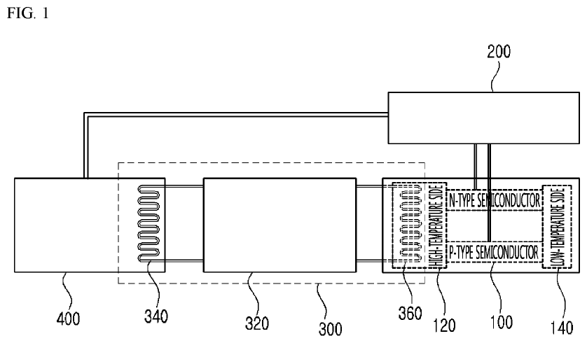

A thermoelectric generator according to a first exemplary embodiment of the present disclosure will be described in greater detail with reference to FIG. 1.

The thermoelectric generator according to the present disclosure includes a thermoelectric element 100, a power generation unit 200 electrically connected to the thermoelectric element 100, a liquid metal heat exchange unit 300 connected to a high-temperature side 120 of the thermoelectric element 100 so as to exchange heat therewith, and a heat source unit 400 connected to the liquid metal heat exchange unit 300 so as to exchange heat therewith.

The power generation unit 200 electrically connected to the thermoelectric element 100 is a generator that uses thermoelectric element, as has already been described in detail above. This will not be redundantly described below.

The liquid metal flows in the liquid metal exchange unit 300. According to the present disclosure, liquid metal refers to a metal present in a liquid state at a certain temperature range, and any metal that has a high thermal capacity and low viscosity is applicable as a liquid metal, although a preferable example may include a liquid metal including one or more of tin, bismuth, lead, and gallium.

The liquid metal heat exchange unit 300 includes a liquid metal storage unit 320, a first liquid metal heat exchanger 340, and a second liquid metal heat exchanger 360.

The first liquid metal heat exchanger 340 is connected to the heat source unit 400 so as to exchange heat therewith. That is, the first liquid metal heat exchanger 340 functions to absorb heat generated from the heat source unit 400, using the liquid metal flowing in the first liquid metal heat exchanger 340. The first liquid metal heat exchanger 340 with any structure that can efficiently exchange heat can be connected to the heat source unit 400 in a suitable manner. For example, the first liquid metal heat exchanger 340 may be connected in a manner of surrounding the heat source unit 400, or penetrating an interior of the heat source unit 400.

The second liquid metal heat exchanger 360 is connected to the high-temperature side 120 of the thermoelectric element 100 so as to exchange heat therewith. That is, the heat of the liquid metal flowing in the second liquid metal heat exchanger 360 is delivered to the high-temperature side 120 of the thermoelectric element 100. The second liquid metal heat exchanger 360 with any structure that can efficiently exchange heat can be connected to the high-temperature side 120 of the thermoelectric element.

The heat exchange, i.e., the transfer of the heat between the thermoelectric element 100 and the second liquid metal heat exchanger 360 includes the heat transfer from the second liquid metal heat exchanger 360 to the thermoelectric element 100, and the heat transfer from the thermoelectric element 100 to the second liquid metal heat exchanger 360. That is, electricity can be supplied to the thermoelectric element 100 to generate heat, and the generated heat can be delivered to the second liquid metal heat exchanger 360, when it is necessary to not only deliver the heat generated at the heat source unit 400 to the thermoelectric element 100, but also add heat to the liquid metal for increased flowability of the liquid metal in case the liquid metal is cooled into solid state.

The liquid metal storage unit 320 is fluidly communicated with the first liquid metal heat exchanger 340 and the second liquid metal heat exchanger 360.

That is, as the liquid metal flows in the first liquid metal heat exchanger 340, the heat generated from the heat source unit 400 is absorbed, and the absorbed heat is delivered by the liquid metal to the liquid metal storage unit 320. Accordingly, the liquid metal circulates through the first liquid metal heat exchanger 340 and the liquid metal storage unit 320, thus delivering the heat generated at the heat source unit 400 to the liquid metal storage unit 320.

The heat delivered through the first liquid metal heat exchanger 340 is then delivered from the liquid metal storage unit 320 to the high-temperature side 120 of the thermoelectric element 100 by the liquid metal flowing to the second liquid metal heat exchanger 360. That is, the heat generated at the heat source unit 400 is delivered by the liquid metal flowing in the liquid metal heat exchange unit 300 to the high-temperature side 120 of the thermoelectric element 100 and accordingly, power generation is achieved.

Because the heat generated at the heat source unit 400 is first passed through the liquid metal storage unit 320 before being delivered to the high-temperature side 120 of the thermoelectric element 100, the heat delivered to the high-temperature side 120 of the thermoelectric element 100 can be adjusted to a predetermined temperature range at the liquid metal storage unit 120 before being delivered. A variety of related technologies, which will not be described in detail herein, may be applied to adjust temperature at the liquid metal storage unit 320.

In a thermoelectric generator using thermoelectric element, a heat transfer means, i.e., the liquid metal heat exchange unit 300 may be separately provided from the heat source unit 400, in which case more heat can be delivered by the large heat-capacity characteristic of the liquid metal, and spatial restriction of the thermoelectric generator is also eliminated.

Circulation of such liquid metal can be achieved by a liquid metal pump (not illustrated) positioned in the liquid metal heat exchange unit 300.

The electricity generated from the power generation unit 200 is supplied to the heat source unit 400. Accordingly, the heat generated from the heat source unit 400, or more specifically, the waste heat can be re-used as an energy source for the heat source unit 400. As a result, energy efficiency is increased.

An example of the heat source unit 400 for generating heat may include a boiler, an automobile engine, an automobile exhaust system, a stove, a barbeque grill, and so on, although those skilled in the art will be easily able to understand that the thermoelectric generator according to the present disclosure is applicable to any place where the heat is generated.

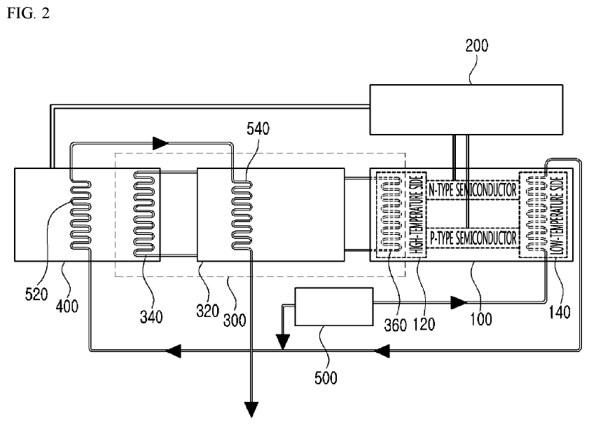

The thermoelectric generator according to the second exemplary embodiment of the present disclosure will be described with reference to FIG. 2. The elements or operations overlapping those already described above with reference to the first exemplary embodiment will not be redundantly described below.

The thermoelectric generator according to the present disclosure includes a water supply unit 500 for supplying water, a first hot water heat exchanger 520, and a second hot water heat exchanger 540.

The water supply unit 500 is connected to the low-temperature side 140 of the thermoelectric element 100. Accordingly, the heat released through the thermoelectric element 100 can be easily cooled. Specifically, in an example of a boiler where such heat source unit 400 generates hot water, the water supplied from the water supply unit 500 is increased in temperature as it passes the low-temperature side 140 of the thermoelectric element 100, when absorbing the heat released from the thermoelectric element 100. Accordingly, use of energy necessary to generate hot water can be saved.

The first hot water heat exchanger 520 is connected to the low-temperature side 140 of the thermoelectric element 100, and supplied with the water passed through the low-temperature side 140 of the thermoelectric element 100. The first hot water heat exchanger 520 is connected to the heat source unit 400 so as to exchange heat therewith, and accordingly, heat is supplied to the water flowing in the first hot water heat exchanger 520, and the temperature of the hot water is increased.

The second hot water heat exchanger 540 is connected to the first hot water heat exchanger 520 to receive the water that passed through the first hot water heat exchanger 520. Accordingly, the water gains certain temperature while passing through the heat source unit 400, and then supplied back to the second hot water heat exchanger 540.

The second hot water heat exchanger 540 is connected to the liquid metal heat exchanger 300, or more specifically, to the liquid metal storage unit 320 so as to exchange heat with the liquid metal storage unit 320. That is, the water, once supplied with the heat from the heat source unit 400, has a further increased temperature as it is again supplied with the heat from the liquid metal storage unit 320. As a result, compared to the related art where the hot water is produced solely by the heat supplied from the heat source 400, the present disclosure provides enhanced energy efficiency as it not only generates electricity, but also produces hot water with the heat supplied from respective places of the thermoelectric generator.

Of course, the hot water can be produced with the water directly supplied from the water supply unit 500 to the first hot water heat exchanger 520 or to the second hot water heat exchanger 540.

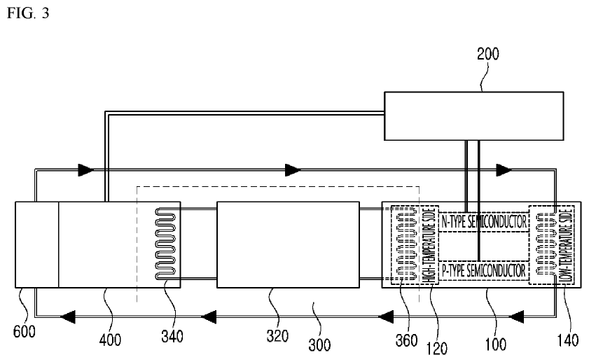

A thermoelectric generator according to a third exemplary embodiment of the present disclosure will be described with reference to FIG. 3.

The thermoelectric generator according to the present disclosure includes a cooling unit 600 connected to the heat source unit 400 to cool the heat source unit 400.

The cooling unit 600 is connected to the low-temperature side 140 of the thermoelectric element 100 such that the coolant of the cooling unit 600 is supplied to the low-temperature side 140 of the thermoelectric element 100 and after passing the low-temperature side 140 of the thermoelectric element 100, the coolant is supplied to the cooling unit 600. That is, the coolant circulates between the cooling unit 600 and the thermoelectric element 100. As a result, the heat released from the thermoelectric element 100 is cooled by the coolant.

The heat source unit 400 may be one or more of automobile engine and automobile exhaust system.

In an example of the automobile engine, the liquid metal flowing in the liquid metal heat exchange unit 300, or more specifically, the liquid metal flowing in the first liquid metal heat exchanger 340 serves as a coolant to cool the engine. The path of the coolant to cool the automobile engine may be same as, or different from the path of the liquid metal in the first liquid metal heat exchanger 340. When the characteristics of the coolant used in the automobile engine to cool the automobile engine are same as the characteristics of the liquid metal, the path of the coolant may be same as the path of the liquid metal.

The present disclosure has been described above with reference to detailed exemplary embodiments as illustrated in the drawings to enable those skilled in the art to be easily able to understand and reproduce the present disclosure. However, these are provided merely for illustrative purpose and it will be understood that various modifications and equivalent other embodiments are possible from the foregoing exemplary embodiments. Accordingly, the scope of the present disclosure should be defined by not only the accompanying claims, but also equivalents to the claims.

What is claimed is:

1. A thermoelectric generator, comprising:
a thermoelectric element 100;
a power generation unit 200 electrically connected to the thermoelectric element 100;
a liquid metal heat exchange unit 300, which is connected to a high-temperature unit 120 of the thermoelectric element 100 so as to exchange heat therewith, and in which a liquid metal flows;
a heat source unit 400 connected to the liquid metal heat exchange unit 300 so as to exchange heat therewith;
a water supply unit 500 connected to the low-temperature unit 140 of the thermoelectric element 100;
a first hot water heat exchanger connected to the low-temperature unit 140 of the thermoelectric element;
wherein water supplied from the water supply unit 500 is passed through the low-temperature unit 140 of the thermoelectric element and then supplied to the first hot water heat exchanger 520, and
the first hot water heat exchanger 520 is connected to the heat source unit 400 so as to exchange heat therewith.

2. The thermoelectric generator of claim 1, further comprising a second hot water heat exchanger 540 connected to the first hot water heat exchanger 520,
wherein water passed through the first hot water heat exchanger 500 is supplied to the second hot water heat exchanger 540, and
the second hot water heat exchanger 540 is connected to the liquid metal heat exchanger 300 so as to exchange heat therewith.

3. The thermoelectric generator of claim 2, wherein the heat source unit 400 is a boiler,
the water supply unit 500 is connected to one or more of the first hot water heat exchanger 520 and the second hot water heat exchanger 540, and
water is supplied from the water supply unit 500 to the first hot water heat exchanger 520, or from the water supply unit 500 to the second hot water heat exchanger 540.

4. The thermoelectric generator of claim 1, wherein the liquid metal heat exchange unit 300 comprises:
a first liquid metal heat exchanger 340 connected to the heat source unit 400;
a second liquid metal heat exchanger 360 connected to the high-temperature unit 120 of the thermoelectric element so as to exchange heat therewith; and
a liquid metal storage unit 320 fluidly communicated with the first liquid metal heat exchanger 340 and the second liquid metal heat exchanger 360.

5. The thermoelectric generator of claim 4, wherein the liquid metal circulates between the first liquid metal heat exchanger 340 and the liquid metal storage unit 320, and between the second liquid metal heat exchanger 360 and the liquid metal storage unit 320.

6. The thermoelectric generator of claim 1, wherein electricity produced at the power generation unit 200 is supplied to the heat source unit 400.

7. The thermoelectric generator of claim 1, wherein the liquid metal is composed of one or more of tin, bismuth, lead, and gallium.
